(19) United States
(12) Patent Application Publication
(10) Pub. No.: US 2011/0017706 A1
(43) Pub. Date: Jan. 27, 2011

(54) PLASMA PROCESSING METHOD AND PLASMA PROCESSING APPARATUS

(75) Inventors: Tetsuro Takahashi, Yamanashi-ken (JP); Yutaka Fujino, Yamanashi-ken (JP); Hiroyuki Toshima, Yamanashi-ken (JP); Atsushi Kubo, Yamanashi-ken (JP); Song Yun Kang, Hyogo-ken (JP); Peter Ventzek, Tokyo-To (JP); Sumie Segawa, Yamanashi-ken (JP)

Correspondence Address: SMITH, GAMBRELL & RUSSELL, 1130 CONNECTICUT AVENUE, N.W., SUITE 1130, WASHINGTON, DC, 20036, US

(73) Assignee: Tokyo Electron Limited, Tokyo-To (JP)

(21) Appl. No.: 12/668,106

(22) PCT Filed: Jul. 10, 2008
(86) PCT No.: PCT/JP2008/062477

§ 371 Date: Oct. 19, 2010

(30) Foreign Application Priority Data
Jul. 11, 2007 (JP) 2007-182030

(51) Int. Cl. C23F 1/08; C23C 16/50; C23F 1/00; C23C 16/511; C23C 16/00

(52) U.S. Cl. 216/69; 427/569; 216/67; 427/575; 118/723 R; 156/345.1; 118/723 AN; 156/345.41; 156/345.41

(57) ABSTRACT

A wafer is disposed in a chamber, a plasma generating space is formed in the chamber, plasma processing is performed to the front surface of the processing object while keeping at least the front surface of the processing object in contact with the plasma generating space. The plasma processing is performed with the plasma generating space being kept in contact with at least the peripheral region of the back surface of the processing object.

### TECHNICAL FIELD

The present invention relates to a plasma processing method and a plasma processing apparatus for carrying out plasma processing of a processing object using a plasma, for example, a microwave plasma.

### BACKGROUND ART

In the manufacturing of various semiconductor devices, plasma processing, such as oxidation, nitridation, etching or film forming, is carried out on a semiconductor wafer as a processing object.

An exemplary nitridation processing is nitridation for the formation of a gate insulating film of an MIS transistor. Known nitridation processes for the formation of a gate insulating film include a process which involves direct nitridation of a silicon substrate to form a gate insulating film of silicon nitride (e.g. Japanese Patent Laid-Open Publication No. 2000-294550), and a process which involves the formation of an oxide film and the subsequent nitridation of the surface of the oxide film (e.g. U.S. Pat. No. 6,660,659). A process is also known which involves nitridation of the surface of a polysilicon capacitor electrode of a DRAM to prevent oxidation of the electrode (e.g. Japanese Patent Publication No. 2007-5696).

As a plasma processing apparatus for carrying out such a nitridation processing, an RLSA microwave plasma processing apparatus as disclosed in the above-cited Japanese Patent Laid-Open Publication Nos. 2000-294550 and 2007-5696 is known which generates a microwave plasma by introducing microwaves into a processing chamber by means of an RLSA (radial line slot antenna) having slots, and carries out plasma processing of a semiconductor substrate, placed on a stage in the chamber, with the microwave plasma generated. The plasma processing apparatus is capable of performing low-damage, high-efficiency processing with a high-density, low-electron temperature plasma.

However, it has turned out that when carrying out nitridation of a semiconductor wafer by means of such an apparatus, the nitridation rate tends to be low in a peripheral region of the semiconductor wafer, resulting in non-uniform nitridation in the surface of the semiconductor wafer.

It has also turned out that such tendency exists also in other types of processing than nitridation and also in processing using a plasma other than a microwave plasma.

### DISCLOSURE OF THE INVENTION

It is an object of the present invention to provide a plasma processing method and a plasma processing apparatus, which make it possible to carry out plasma processing with high in-plane uniformity.

It is another object of the present invention to provide a storage medium in which is stored a program for use in carrying out a plasma processing method capable of performing plasma processing with high in-plane uniformity.

According to a first aspect of the present invention, there is provided a plasma processing method comprising: disposing a processing object in a processing container; forming a plasma generating space in the processing container; and carrying out plasma processing of the front surface of the processing object while keeping at least the front surface of the processing object in contact with the plasma generating space, wherein the plasma generating space is also kept in contact with at least a peripheral region of the back surface of the processing object during the plasma processing.

In a preferred embodiment of the first aspect of the present invention, a processing object stage section, including a plate and a processing object lifting member which is projectable and retractable with respect to the plate, is provided in the processing container, and the processing object is placed on the processing object lifting member projecting a predetermined distance from the plate, whereby a plasma generating space of the predetermined distance, in contact with at least the peripheral region of the back surface of the processing object, is formed between the plate and the processing object. The predetermined distance between the plate and the processing object is preferably not less than 0.3 mm.

In another preferred embodiment of the first aspect of the present invention, a stage for placing the processing object thereon and which has a smaller diameter than the processing object is provided in the processing container, and the processing object is placed on the stage with a peripheral portion of the processing object projecting from the edge of the stage, whereby the plasma generating space formed in the processing container is also in contact with at least the peripheral region of the back surface of the processing object.

According to a second aspect of the present invention, there is provided a plasma processing method comprising: disposing a processing object in a processing container; forming a plasma generating space in the processing container; and carrying put plasma processing of the front surface of the processing object while keeping at least the front surface of the processing object in contact with the plasma generating space, wherein there is substantially no member that blocks the plasma in an area around the periphery of the processing object, and the plasma processing is carried out in the plasma which also exists below the front surface of the processing object in the area around the periphery of the processing object.

In the second aspect of the present invention, the plasma preferably also exists 2 to 12 mm below the front surface of the processing object in the area around the periphery of the processing object.

In the first and second aspects of the present invention, the plasma processing may be plasma nitridation processing. Further, the plasma processing may be carried out by means of a microwave plasma.

According to a third aspect of the present invention, there is provided a plasma processing apparatus comprising: a processing container for housing a processing object; a processing object stage section, disposed in the processing container, for placing the processing object thereon; a gas supply mechanism for supplying a processing gas into the processing container; a plasma-forming means for forming a plasma of the processing gas in the processing container; and a control section for controlling the processing object stage section, wherein the processing object stage section includes a plate, a processing object lifting member, projectable and retractable with respect to the plate, for supporting and vertically moving the processing object, and a lifting mechanism for driving the processing object lifting member, and wherein the control section controls the lifting mechanism such that the processing object lifting member projects a predetermined distance from the plate so that a plasma generating space of the predetermined distance, in contact with at least a peripheral region of the back surface of the processing object, is formed between the plate and the processing object placed on the processing object lifting member.

In the third aspect of the present invention, the control section preferably controls the lifting mechanism such that the distance between the plate and the processing object becomes not less than 0.3 mm.

According to a fourth aspect of the present invention, there is provided a plasma processing apparatus comprising: a processing container for housing a processing object; a processing object stage section, disposed in the processing container, for placing the processing object thereon; a gas supply mechanism for supplying a processing gas into the processing container; and a plasma-forming means for forming a plasma of the processing gas in the processing container, wherein the processing object stage section includes a stage having a smaller diameter than the diameter of the processing object, and wherein the processing object is placed on the stage with a peripheral portion of the processing object projecting from the edge of the stage, whereby a plasma generating space formed in the processing container is also in contact with at least a peripheral region of the back surface of the processing object.

According to a fifth aspect of the present invention, there is provided a plasma processing apparatus comprising: a processing container for housing a processing object; a processing object stage section, disposed in the processing container, for placing the processing object thereon; a gas supply mechanism for supplying a processing gas into the processing container; a plasma-forming means for forming a plasma of the processing gas in the processing container; and a control section for controlling the processing object stage section, wherein there is substantially no member that blocks the plasma in an area around the periphery of the processing object when it is placed on the processing object stage section, and the plasma also exists below the front surface of the processing object in the area around the periphery of the processing object.

In the fifth aspect of the present invention, the processing object stage section preferably includes a ceramic susceptor and a susceptor cover covering the entire upper surface of the susceptor and having a flat receiving surface for placing the processing object thereon. The susceptor cover preferably has a lower-level surface positioned around and 3 to 12 mm below the receiving surface.

In the third to fifth aspects of the present invention, the processing gas may comprise a nitrogen-containing gas for plasma nitridation processing. The plasma-forming means may include a microwave introduction means, having a plane antenna having a plurality of slots, for introducing microwaves into the processing container via the plane antenna, and turn the processing gas into plasma by means of the microwaves introduced.

According to the present invention, plasma processing of a processing object is carried out in such a manner that a plasma generating space is also in contact with at least a peripheral region of the back surface of the processing object. This can increase the amount of active species, contributing to plasma processing, in a peripheral region of the front surface of the processing object and consequently, increase the plasma processing rate in the peripheral region of the processing object where the plasma processing rate would otherwise be low. It thus becomes possible to carry out plasma processing with high in-plane uniformity.

Also according to the present invention, there is substantially no member that blocks a plasma in an area around the periphery of a processing object, and plasma processing is carried out in the plasma which also exists below the front surface of the processing object in the area around the periphery of the processing object. This allows a larger amount of active species in the plasma to reach a peripheral region of the front surface of the processing object, thereby eliminating the tendency to low amount of nitrogen introduced into the peripheral region of the front surface of the processing object. It thus becomes possible to carry out plasma processing with high in-plane uniformity.

### BRIEF DESCRIPTION OF THE DRAWINGS

FIG. 1 is a cross-sectional diagram showing a plasma processing apparatus according to a first embodiment of the present invention;

FIG. 2 is a diagram showing the structure of the plane antenna member of the plasma processing apparatus of FIG. 1;

FIG. 3 is a timing chart showing a process sequence in the plasma processing apparatus according to the first embodiment of the present invention;

FIG. 4 is a diagram illustrating plasma processing of a wafer as carried out according to the first embodiment of the present invention;

FIG. 5 is a diagram illustrating conventional plasma processing;

FIG. 6 is a schematic diagram illustrating the first embodiment of the present invention;

FIGS. 7A through 7C are diagrams illustrating an experiment to verify the advantageous effect of the present invention;

FIG. 8 is a graph showing the relationship between the height of a wafer from a susceptor and the difference in the thickness of a nitride film between the center and the edge of the wafer, as observed in direct nitridation of silicon;

FIG. 9 is a graph showing the relationship between the height of a wafer from a susceptor and in-plane variation in the thickness of a nitride film between the center and the edge of the wafer, as observed in direct nitridation of silicon;

FIG. 10 is a graph showing the relationship between the height of a wafer from a susceptor and the difference in the nitrogen concentration of a nitride film between the center and the edge of the wafer, as observed in nitridation of a silicon oxide film;

FIG. 11 is a graph showing the relationship between the height of a wafer from a susceptor and in-plane variation in the nitrogen concentration of a nitride film between the center and the edge of the wafer, as observed in nitridation of a silicon oxide film;

FIG. 12 is a cross-sectional diagram showing a plasma processing apparatus according to a second embodiment of the present invention;

FIG. 13 is an enlarged view of the susceptor of the plasma processing apparatus of FIG. 12;

FIG. 14 is a cross-sectional diagram showing a plasma processing apparatus according to a third embodiment of the present invention;

FIG. 15 is a plan view of the susceptor cover of the plasma processing apparatus of FIG. 14;

FIG. 16A is a cross-sectional diagram illustrating plasma processing of a wafer as carried out in a conventional plasma processing apparatus, and FIG. 16B is a cross-sectional diagram illustrating plasma processing of a wafer as carried out in the plasma processing apparatus according to the third embodiment of the present invention;

FIG. 17 is a graph showing the advantageous effect of the third embodiment of the present invention; and

FIG. 18A is a diagram showing the relationship between distance H1 and “the range of the amount of nitrogen introduced/2×average”; and

FIG. 18B is a diagram showing the relationship between distance H1 and “1σ a of the amount of nitrogen introduced/average”.

### BEST MODE FOR CARRYING OUT THE INVENTION

Preferred embodiments of the present invention will now be described with reference to the drawings.

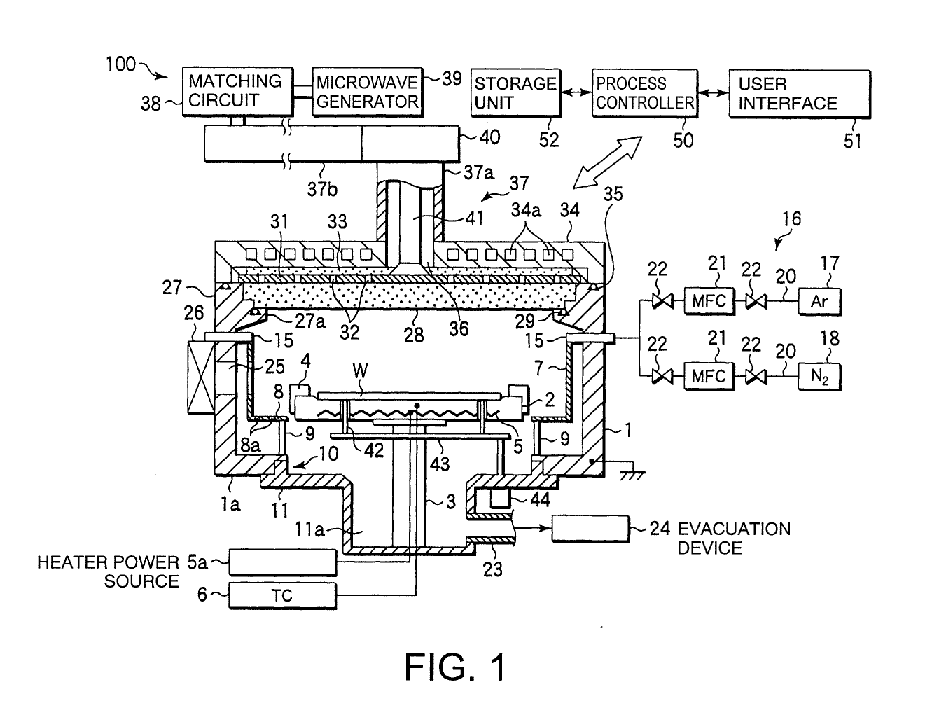

FIG. 1 is a cross-sectional diagram showing a plasma processing apparatus according to a first embodiment of the present invention. The plasma processing apparatus is constructed as an RLSA microwave plasma processing apparatus capable of generating a high-density, low-electron temperature microwave plasma by introducing microwaves into a processing chamber by means of an RLSA (radial line slot antenna), which is a plane antenna having a plurality of slots. The plasma processing apparatus is adapted to carry out plasma nitridation processing.

The plasma processing apparatus 100 includes a generally-cylindrical airtight and grounded chamber 1. A circular opening 10 is formed generally centrally in the bottom wall 1a of the chamber 1. The bottom wall 1a is provided with a downwardly-projecting exhaust chamber 11 which communicates with the opening 10.

In the chamber 1 is provided a susceptor 2, made of a ceramic, especially an Al-containing ceramic such as AlN, for horizontally placing thereon a wafer W as a substrate to be processed. The susceptor 2 is supported by a cylindrical support member 3, made of a ceramic such as AlN, extending upwardly from the center of the bottom of the exhaust chamber 11. The susceptor 2, in its peripheral portion, is provided with a ring-shaped susceptor cover 4 made of quartz. The susceptor cover 4 functions to prevent the susceptor 2 from being damaged by plasma. The susceptor 2 and the susceptor cover 4 constitute a wafer stage section. A resistance heating-type heater 5 is embedded in the susceptor 2. The heater 5, when powered from a heater power source 5a, heats the susceptor 2 and, by the heat, heats the wafer W as a processing object.

The susceptor (stage) 2 is also provided with a thermocouple 6 so that the heating temperature of the wafer W can be controlled e.g. in the range of room temperature to 900° C. A cylindrical liner 7 of quartz is provided on the inner circumference of the chamber 1. The liner 7 can prevent contamination of a wafer with a metal coming from the chamber. Further, an annular baffle plate 8, having a plurality of holes 8a for uniformly evacuating the chamber 1, is provided around the circumference of the susceptor 2. The baffle plate 8 is supported on support posts 9.

The susceptor 2 is provided with three wafer support pins 42 (only two pins are shown) for raising and lowering the wafer W while supporting it. The wafer support pins 42 are projectable and retractable with respect to the surface of the susceptor 2, and are fixed on a support plate 43. The wafer support pins 42 are raised and lowered via the support plate 43 by means of a drive mechanism 44, such as an air cylinder. The wafer support pins 42 is composed of, for example, a ceramic, such as Al₂O₃, or quartz. It is also possible to use four or more wafer support pins.

An annular gas introduction member 15 is provided in the side wall of the chamber 1. A gas supply system 16 is connected to the gas introduction member 15. It is also possible to use a gas introduction member having the shape of a shower head. The gas supply system 16 has, for example, an Ar gas supply source 17 and an N₂ gas supply source 18. These gases each pass through a respective gas line 20 and reach the gas introduction member 15, and are introduced from the gas introduction member 15 into the chamber 1. The gas lines 20 are each provided with a mass flow controller 21 and on-off valves 22 located upstream and downstream of the controller 21. Instead of N₂ gas, NH₃ gas, a mixed gas of N₂ and H₂, etc. may also be used. Further, instead of Ar gas, other rare gases such as Kr, He, Ne and Xe may also be used. It is also possible not to use any rare gas.

An exhaust pipe 23 is connected to the side wall of the exhaust chamber 11, and to the exhaust pipe 23 is connected an exhaust device 24 including a high-speed vacuum pump. By the actuation of the exhaust device 24, the gas in the chamber 1 is uniformly discharged into the space 11a of the exhaust chamber 11, and discharged through the exhaust pipe 23 to the outside. The chamber 1 can thus be quickly depressurized into a predetermined vacuum level, e.g. 0.133 Pa.

The side wall of the chamber 1 is provided with a transfer port 25 for transferring the wafer W between the plasma processing apparatus 100 and an adjacent transfer chamber (not shown), and a gate valve 26 for opening and closing the transfer port 25.

The chamber 1 has a top opening, and a ring-shaped support 27 is provided along the periphery of the opening. A microwave-transmissive plate 28, which is made of a dielectric material, e.g. quartz or a ceramic such as Al₂O₃ or AlN, and is transmissive to microwaves, is provided on the support 27. A seal member 29 for airtight sealing is provided between the microwave-transmissive plate 28 and the support 27 so that the chamber 1 can be kept hermetic.

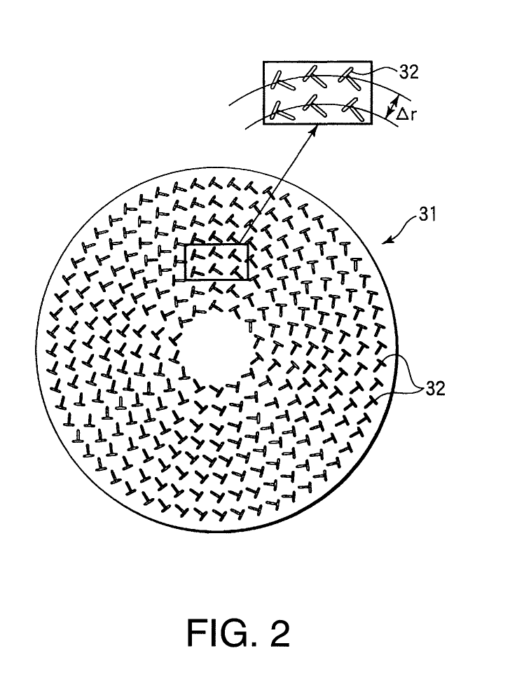

A disk-shaped plane antenna member 31 is provided over the microwave-transmissive plate 28 such that it faces the susceptor 2. The plane antenna member 31 is locked into the upper end of the side wall of the chamber 1. The plane antenna member 31 is comprised of, for example, a copper or aluminum plate whose surface is plated with silver or gold, and has a large number of microwave radiating holes (slots) 32 penetrating the plane antenna member 31 and formed in a predetermined pattern. As shown in FIG. 2, each microwave radiating hole 32 is a slot-like hole, and adjacent two microwave radiating holes 32 are paired typically in a letter “T” arrangement. The pairs of microwave radiating holes 32 are arranged in concentric circles as a whole. The length of the microwave radiating holes 32 and the spacing in their arrangement are determined depending on the wavelength (Ag) of microwaves. For example, the microwave radiating holes 32 are arranged with a spacing of λg/4 to λg. In FIG. 2, the spacing between adjacent concentric lines of microwave radiating holes 32 is denoted by Δr. The microwave radiating holes 32 may have other shapes, such as a circular shape and an arch shape. The arrangement of the microwave radiating holes 32 is not limited to the concentric arrangement: the microwave radiating holes 32 may be arranged e.g. in a spiral or radial arrangement.

A retardation member 33, having a higher dielectric constant than vacuum, is provided on the upper surface of the plane antenna member 31. The retardation member 33 may be formed of a material such as quartz, a ceramic or a fluororesin. The retardation member 33 is employed in consideration of the fact that the wavelength of microwaves becomes longer in vacuum. The retardation member 33 functions to shorten the wavelength of microwaves, thereby adjusting plasma. The plane antenna member 31 and the microwave-transmissive plate 28, and the retardation member 33 and the plane antenna member 31 may be in contact with or spaced apart from each other.

A conductive cover 34, made of a metal material such as aluminum, stainless steel or copper, is provided on the upper surface of the chamber 1 such that it covers the plane antenna member 31 and the retardation member 33. The contact area between the upper surface of the chamber 1 and the conductive cover 34 is sealed with a seal member 35. A cooling water flow passage 34a is formed in the interior of the conductive cover 34. The conductive cover 34, the retardation member 33, the plane antenna member 31 and the microwave-transmissive plate 28 are cooled by passing cooling water through the cooling water flow passage 34a. The conductive cover 34 is grounded.

An opening 36 is formed in the center of the upper wall of the conductive cover 34, and a waveguide 37 is connected to the opening 36. The other end of the waveguide 37 is connected via a matching circuit 38 to a microwave generator 39. Thus, microwaves e.g. having a frequency of 2.45 GHz, generated in the microwave generator 39, are propagated through the waveguide 37 to the plane antenna member 31. Other microwave frequencies, such as 8.35 GHz, 1.98 GHz, etc., can also be used.

The waveguide 37 is comprised of a coaxial waveguide 37a having a circular cross-section and extending upward from the opening 36 of the conductive cover 34, and a horizontally-extending rectangular waveguide 37b connected via a mode converter 40 to the upper end of the coaxial waveguide 37a. The mode converter 40 between the rectangular waveguide 37b and the coaxial waveguide 37a functions to convert microwaves, propagating in TE mode through the rectangular waveguide 37b, into TEM mode. An inner conductor 41 extends centrally in the coaxial waveguide 37a. The lower end of the inner conductor 41 is connected and secured to the center of the plane antenna member 31. Thus, microwaves are propagated through the inner conductor 41 of the coaxial waveguide 37a to the plane antenna member 31 uniformly and efficiently.

The components of the plasma processing apparatus 100 are each connected to and controlled by a process controller 50 provided with a microprocessor (computer). Connected to the process controller 50 is a user interface 51 which includes a keyboard for an operator to perform a command input operation, etc. in order to manage the plasma processing apparatus 100, a display which visualizes and displays the operating situation of the plasma processing apparatus 100, etc. Connected also to the process controller 50 is a storage unit 52 in which are stored a control program for executing, under control of the process controller 50, various process steps to be carried out in the plasma processing apparatus 100, and a program, or a recipe, for causing the respective components of the plasma processing apparatus 100 to execute their processing in accordance with processing conditions. The recipe is stored in a storage medium in the storage unit 52. The storage medium may be a hard disk or a semiconductor memory, or a portable medium such as CD-ROM, DVD, flash memory, etc. It is also possible to transmit the recipe from another device e.g. via a dedicated line as needed.

A desired processing in the plasma processing apparatus 100 is carried out under the control of the process controller 50 by calling up an arbitrary recipe from the storage unit 52 and causing the process controller 50 to execute the processing recipe, e.g. through the operation of the user interface 51 performed as necessary.

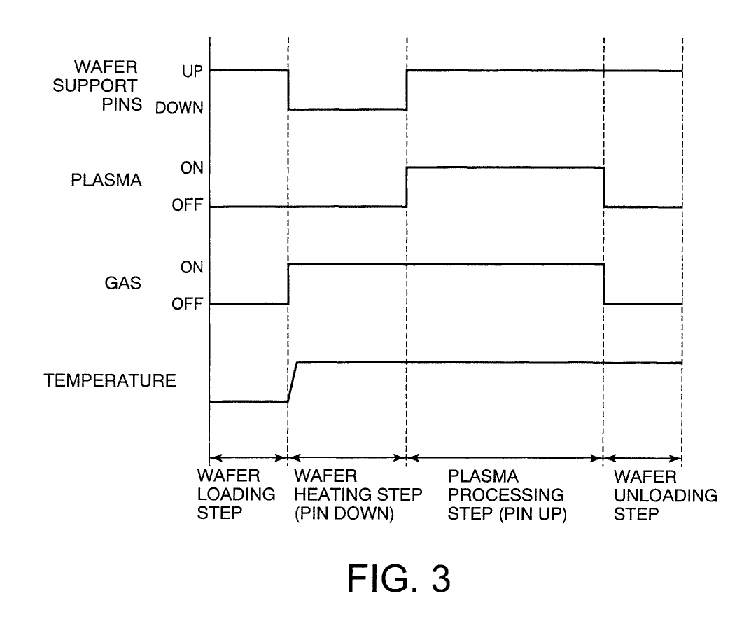

In the RLSA plasma processing apparatus 100 thus constructed, nitridation processing of a wafer W is carried out in the following manner. The processing sequence is shown by the timing chart of FIG. 3.

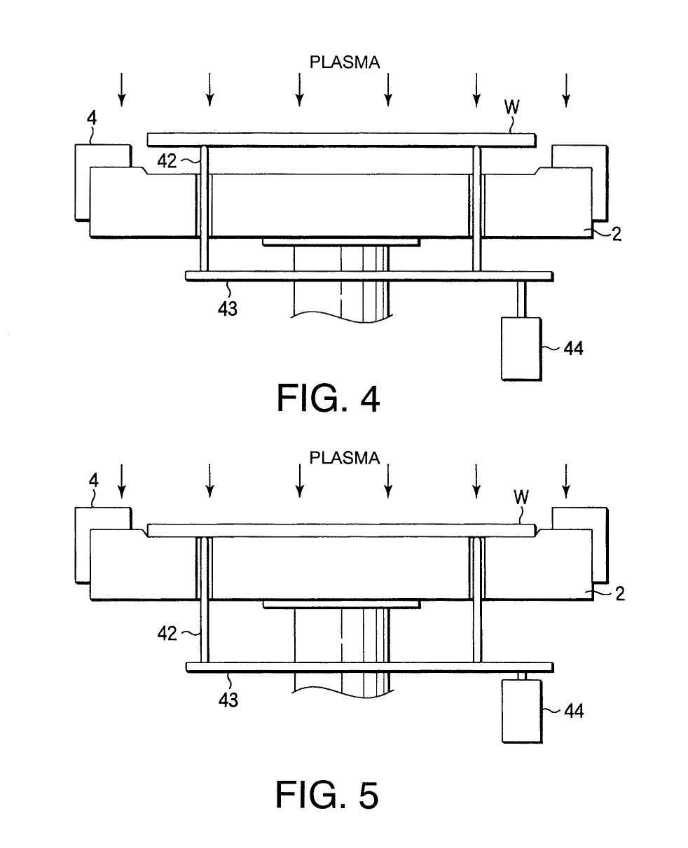

First, the gate valve 26 is opened, and a wafer W on a transfer arm is carried from the transfer port 25 into the chamber 1 (wafer loading step). The wafer support pins 42 are in a raised position, projecting from the susceptor 2 (pin up), and the wafer W is placed on the support pins 42. Thereafter, Ar gas and N₂ gas, each at a predetermined flow rate, are introduced from the Ar gas supply source 17 and the N₂ gas supply source 18 of the gas supply system 16 into the chamber 1 via the gas introduction member 15. The wafer support pins 42 are lowered (pin down) to place the wafer W on the susceptor 2 heated to a predetermined temperature, thereby raising the temperature of the wafer W and carrying out heat treatment (heat treatment step). Thereafter, the wafer support pins 42 are raised (pin up) until the wafer W reaches a position a predetermined distance above the susceptor 2 as shown in FIG. 4. The distance or height of the wafer W from the susceptor 2 can be arbitrarily controlled through control of the drive mechanism 44 by the process controller 50. Microwaves are then introduced into the chamber 1 to carry out plasma processing (plasma processing step). Thereafter, the formation of plasma (supply of microwaves) and the supply of the gases are stopped, and the pressure in the chamber 1 is adjusted to a predetermined degree of vacuum. Thereafter, the wafer W is carried out (wafer unloading step).

The plasma processing conditions are as follows:

The flow rate of a rare gas, such as Ar gas, is 100 to 6000 mL/min (sccm), the flow rate of N₂ gas is 50 to 750 mL/min (sccm), the Ar/N₂ flow rate ratio is 2 to 8, preferably 3 to 6; the processing pressure in the chamber is 10 to 1333 Pa (75 mTorr to 10 Torr), preferably 20 to 333.3 Pa (150 mTorr to 2.5 Torr); and the heating temperature of the wafer W is 250 to 800° C., preferably 400 to 800° C. From the viewpoint of thermal damage to the wafer, it is preferred to use a low temperature such as 300 to 500° C.

The introduction of microwaves is performed as follows: Microwaves from the microwave generator 39 are introduced via the matching circuit 38 into the waveguide 37. The microwaves are then passed through the rectangular waveguide 37b, the mode converter 40 and the coaxial waveguide 37a, and supplied through the inner conductor 41 to the plane antenna 31. The microwaves are then radiated from the microwave radiating holes 32 of the plane antenna member 31 through the microwave-transmissive plate 28 into the space above the wafer W in the chamber 1. The microwaves propagate in TE mode in the rectangular waveguide 37b, the TE mode of the microwaves is converted into TEM mode by the mode converter 40 and the TEM mode microwaves are propagated in the coaxial waveguide 37a toward the plane antenna member 31. By the microwaves radiated from the plane antenna member 31 into the chamber 1 via the microwave-transmissive plate 28, an electromagnetic field is formed in the chamber 1, and a plasma of the Ar gas and the N₂ gas is generated. The power of the microwave generator 39 is preferably 1 to 5 kW (0.5 to 2.6 W/cm²), more preferably 2 to 4 kW (1.0 to 2.1 W/cm²).

Because the microwaves are radiated from the large number of microwave radiating holes 32 of the plane antenna member 31, the microwave plasma has a high density of about 1×10¹⁰ to 5×10¹²/cm³ and, in the vicinity of the wafer W, has a low electron temperature of not more than about 1.5 eV, or even not more than 1.0 eV. Such plasma can perform radical-based processing with little damage to a base material.

The plasma nitridation processing of this embodiment can be applied to a process for nitriding the surface of a silicon oxide film or a ferroelectric oxide film and to a process for directly nitriding a silicon substrate. The former process is typified by nitridation of a gate insulating film in an MIS transistor, and the latter process is typified by nitridation for the formation of a gate insulating film of silicon nitride in an MIS transistor. The present plasma processing can also be applied to nitridation of the surface of a polysilicon film e.g. for use as a capacitor of a DRAM.

It is common practice in conventional plasma nitridation to place a wafer W on the susceptor 2 with the entire back surface of the wafer W in contact with the susceptor 2 as shown in FIG. 5. It has turned out that in this case the amount of nitrogen introduced tends to be low in a peripheral region of the front surface of the wafer W. This is considered to be due to the fact that the amount of active species, contributing to nitridation, is lower in the peripheral region of the front surface of the wafer W than in the central region.

As a result of studies on a method for increasing the amount of active species, contributing to nitridation, in a peripheral region of the front surface of a wafer W, the present inventors have found a method which involves bringing a plasma generating space into contact not only with the front surface and the edge surface of the wafer W but also with at least a peripheral region of the back surface. To allow such contact of a plasma generating space with a peripheral region of the back surface of a wafer W, in this embodiment the wafer W is held on the wafer support pins 42 at a position a predetermined distance above the susceptor 2 during plasma nitridation processing, as shown in FIG. 4.

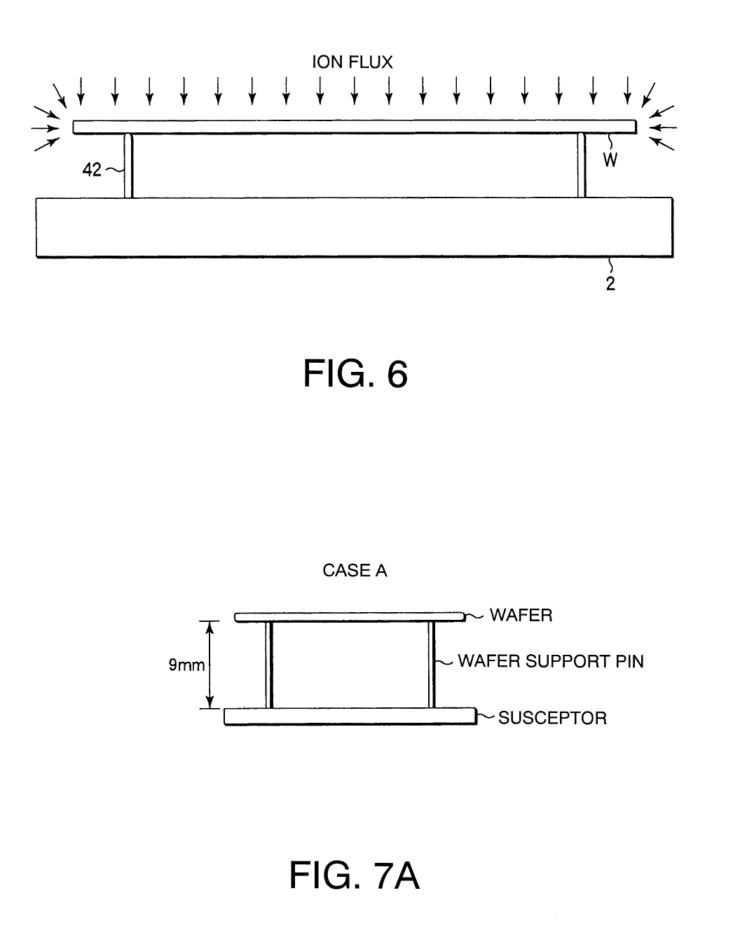

When a plasma generating space is allowed to be in contact with the peripheral region of the back surface of the wafer W in this manner, the plasma can reach a peripheral portion of the wafer W without being blocked by the susceptor 2 and the susceptor cover 4 as shown in FIG. 6. This can increase the amount of ion flux in the peripheral portion, thus increasing the amount of active species, contributing to nitridation, in a peripheral region of the front surface of the wafer W.

It therefore becomes possible to eliminate the tendency to low amount of nitrogen introduced into the peripheral region of the front surface of the wafer W and to thereby reduce the difference in the amount of nitrogen introduced between the central region and the peripheral region of the wafer, making it possible to perform nitridation processing with high in-plane uniformity.

The height of the wafer W on the wafer support pins 42 from the surface of the susceptor 2 is preferably not less than 0.3 mm. This can sufficiently produce the effect of increasing the rate of nitridation in a peripheral region of the front surface of the wafer W. In the case of nitridation of a silicon oxide film, the height of the wafer W is more preferably not less than 3 mm, even more preferably 3 to 12 mm, most preferably 4 to 9 mm. In the case of direct nitridation of silicon, the height of the wafer W is more preferably not less than 3 mm, even more preferably 3 to 12 mm, most preferably 8 to 12 mm. By adjusting the height of the wafer W on the wafer support pins 42, the rate of nitridation in a peripheral region of the front surface of the wafer W can be controlled at a desired value depending on the plasma nitridation conditions.

According to the present invention, the low rate of nitridation in a peripheral region of the wafer W can be eliminated based on the above-described principle. The principle is not limited to a microwave plasma as described above, but can be applied to other plasmas such as an inductive coupled plasma (IPC), a surface wave plasma, a surface-reflected wave plasma, a magnetron plasma, etc.

A description will now be given of experiments which were conducted to verify the advantageous effect of this embodiment.

An experiment is first described which verifies the fact that the increase in the rate of nitridation in a peripheral region of a wafer, brought about by the raising of the wafer by means of the wafer support pins, is due to the formation of a space under the back surface of the wafer.

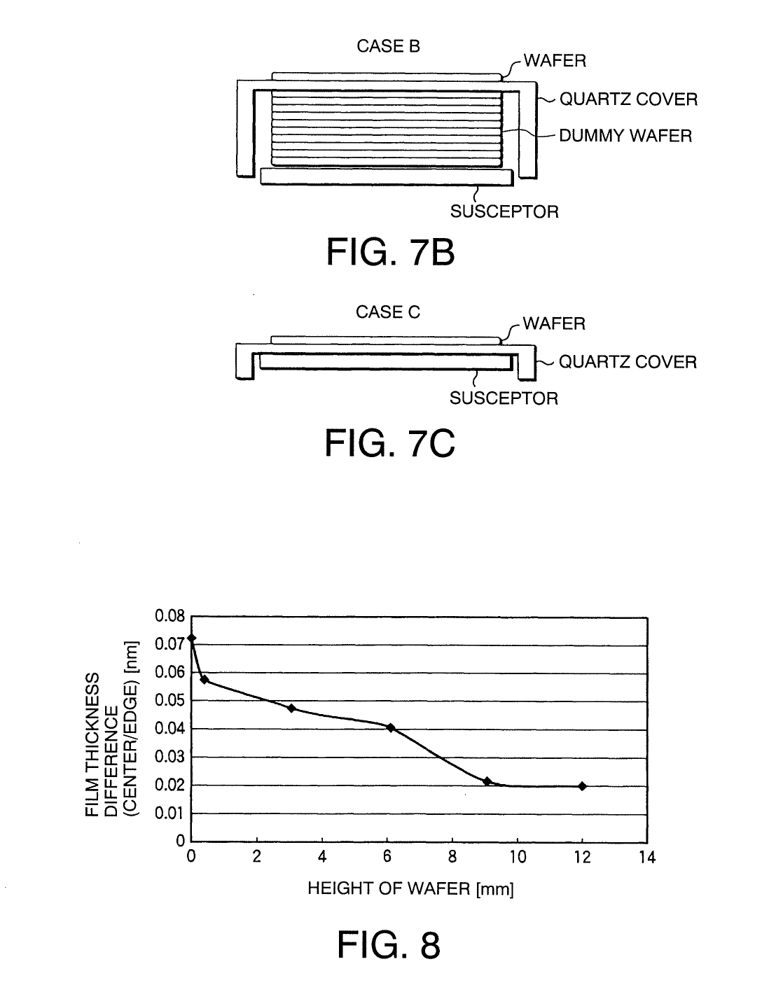

In this experiment, plasma nitridation processing of a silicon oxide film was carried out for wafers W in the following cases A to C: In the case A, as shown in FIG. 7A, the wafer support pins are projected from the susceptor to bring a wafer W into a position at a height of 9 mm from the susceptor so that a plasma generating space can be formed also under the back surface of the wafer W in accordance with the present invention. In the case B, as shown in FIG. 7B, 10 dummy wafers, each having a thickness of 0.75 mm, are piled up on the susceptor, a quartz cover having a thickness of 1.5 mm is placed on the top dummy wafer to ensure a height of 9 mm, and a wafer W is placed on the quartz cover. In the case C, as shown in FIG. 7C, the same quartz cover is placed on the susceptor, and a wafer W is placed on the quartz cover. The case C represents prior art.

The nitridation processing conditions are as follows:

Pressure in the chamber: 20 Pa
Processing gas flow rate: Ar/N₂=1000/200 mL/min (scan)
Microwave power: 2300 W
Processing temperature: normal temperature
Processing time: 35 sec

After the nitridation processing, the nitrogen concentration of the nitrided silicon oxide film was measured at one central point and 24 edge points in the front surface of each wafer W, and in-plane variation was determined by subtracting the average value of the nitrogen concentrations at the 24 edge points from the concentration value at the one central point. As a result, the variation was −0.03 atom % for the case A according to the present invention, whereas the variation was 0.39 atom % for the prior art case C. The variation of the case B was 0.32 atom % which is nearly equal to that of the case C. The data verifies the fact that the technical effect, produced by raising a wafer by means of the wafer support pins in carrying out plasma nitridation processing, is not due to the height of the wafer but due to the formation of a plasma space under the back surface of the wafer.

Next, a description is given of an experiment which was conducted to determine the relationship between the height of a wafer on the wafer support pins and in-plane uniformity of nitridation processing.

In this experiment, using the apparatus of FIG. 1, plasma nitridation processing was carried out with varying heights, ranging from 0 to 12 mm, of a wafer from the susceptor, adjusted by means of the wafer support pins.

Direct nitridation of silicon and nitridation of a silicon oxide film (thickness 1.9 nm) were carried out. The respective plasma nitridation conditions are as follows:

<Direct nitridation of silicon>
Pressure in the chamber: 20 Pa
Processing gas flow rate: Ar/N₂=1000/200 mL/min (sccm)
Microwave power: 2500 W
Processing temperature: 400° C.
Processing time: 35 sec
<Nitridation of silicon oxide film>
Pressure in the chamber: 20 Pa
Processing gas flow rate: Ar/N₂=1000/200 mL/min (sccm)
Microwave power: 2300 W

Processing temperature: 400° C.

Processing time: 35 sec

After the direct nitridation of silicon, the thickness of the nitride film formed was measured at 49 points in the front surface of each wafer W, and the difference in the film thickness between the center and the edge of the wafer and in-plane variation in the film thickness were determined. In the case of nitridation of the silicon oxide film, the nitrogen concentration of the nitrided silicon oxide film was measured at 49 points in the front surface of each wafer W after the nitridation processing, and the difference in the nitrogen concentration between the center and the edge of the wafer and in-plane variation in the nitrogen concentration were determined. The in-plane variation in this test was determined by 1σ/average×100 (%).

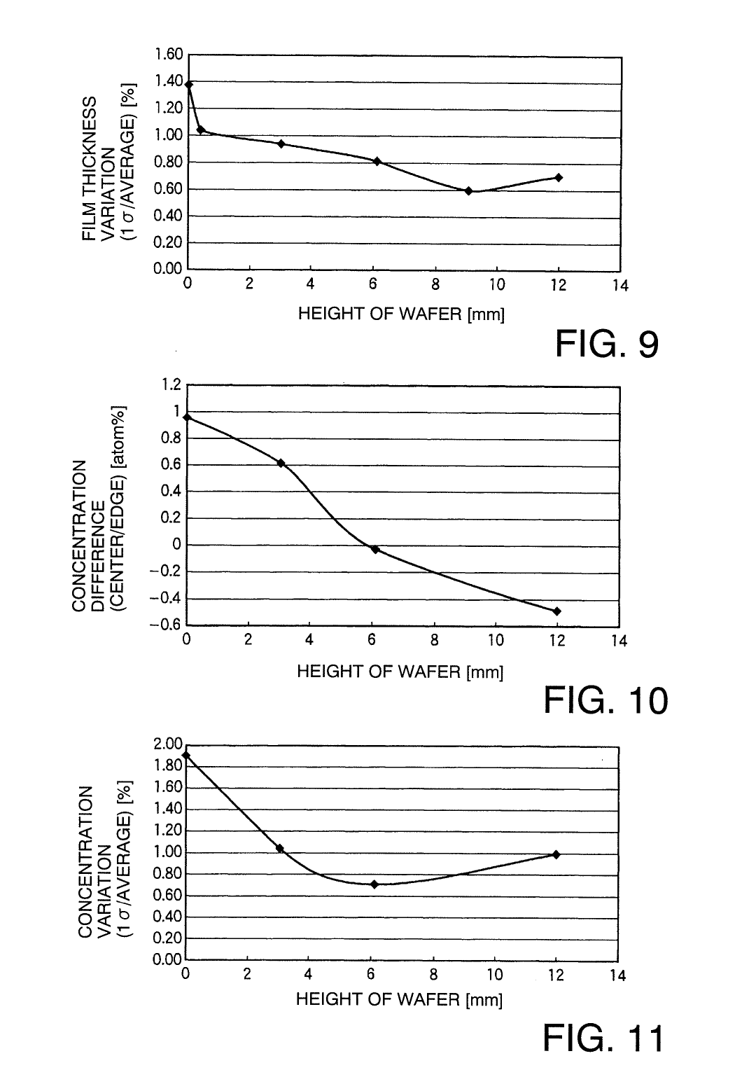

FIG. 8 shows the relationship between the height of a wafer from the susceptor and the difference in the film thickness between the center and the edge of the wafer, observed in the direct nitridation processing of silicon, and FIG. 9 shows the relationship between the height of a wafer from the susceptor and the in-plane variation in the film thickness, observed in the direct nitridation processing of silicon. By forming a space between the susceptor and a wafer by the wafer support pins, a broadened plasma which is uniform over the entire front surface, including the periphery, of the wafer can be formed. This reduces the film thickness difference between the center and the periphery of the wafer, as shown in FIG. 8, and also reduces in-plane variation in the film thickness, as shown in FIG. 9. The data in the Figures also indicates that the film thickness difference between the center and the periphery of a wafer and the in-plane variation in the film thickness tend to decrease with increase in the distance between the susceptor and the wafer, and that the variation shows a remarkable drop at the distance of about 0.3 mm and has a minimum at the distance of 9 mm. As can be seen from the data, the distance between the susceptor and a wafer is preferably not less than 0.3 mm and not more than 12 mm in view of the film thickness difference and the variation. Further, in view of the fact that the variation is less that 1% when the distance is not less than 3 mm and also in view of a margin, the distance between the susceptor and a wafer is more preferably not less than 2.5 mm, even more preferably not less than 3 mm.

FIG. 10 shows the relationship between the height of a wafer from the susceptor and the difference in the nitrogen concentration of the nitrided silicon oxide film between the center and the periphery of the wafer, observed in the nitridation processing of the silicon oxide film, and FIG. 11 shows the relationship between the height of a wafer from a susceptor and in-plane variation in the nitrogen concentration of the nitrided silicon oxide film between the center and the periphery of the wafer, observed in the nitridation processing of the silicon oxide film. The data in the Figures verifies that the formation of a space between the susceptor and a wafer by the wafer support pins reduces the difference in the amount of nitrogen introduced between the center and the periphery of the wafer, as shown in FIG. 10, and also reduces in-plane variation in the nitrogen concentration, as shown in FIG. 11. The data in the Figures also indicates that the nitrogen concentration difference between the center and the periphery of a wafer and the in-plane variation in the nitrogen concentration tend to decrease with increase in the distance between the susceptor and the wafer, and that the variation shows a remarkable drop even at the distance of about 0.3 mm and has a minimum at the distance of 6 mm. As can be seen from the data, the distance between the susceptor and a wafer is again preferably not less than 0.3 mm and not more than 12 mm in view of the difference and variation in the nitrogen concentration. Further, in view of the fact that the variation is not more than 1% when the distance is not less than 3 mm and also in view of a margin, the distance between the susceptor and a wafer is more preferably not less than 2.5 mm, even more preferably not less than 3 mm.

The experimental results thus verify the following facts: Regardless of whether direct nitridation of silicon or nitridation of an oxide film, the amount of nitrogen introduced into a peripheral region of a wafer increases by the formation of a space between the susceptor and the wafer by the wafer support pins, resulting in enhanced in-plane uniformity of nitridation processing. The effect tends to increase with increase in the distance of a wafer from the susceptor; and the distance is preferably not less than 0.3 mm and not more than 12 mm. The distance is more preferably not less than 2.5 mm, and even more preferably not less than 3 mm.

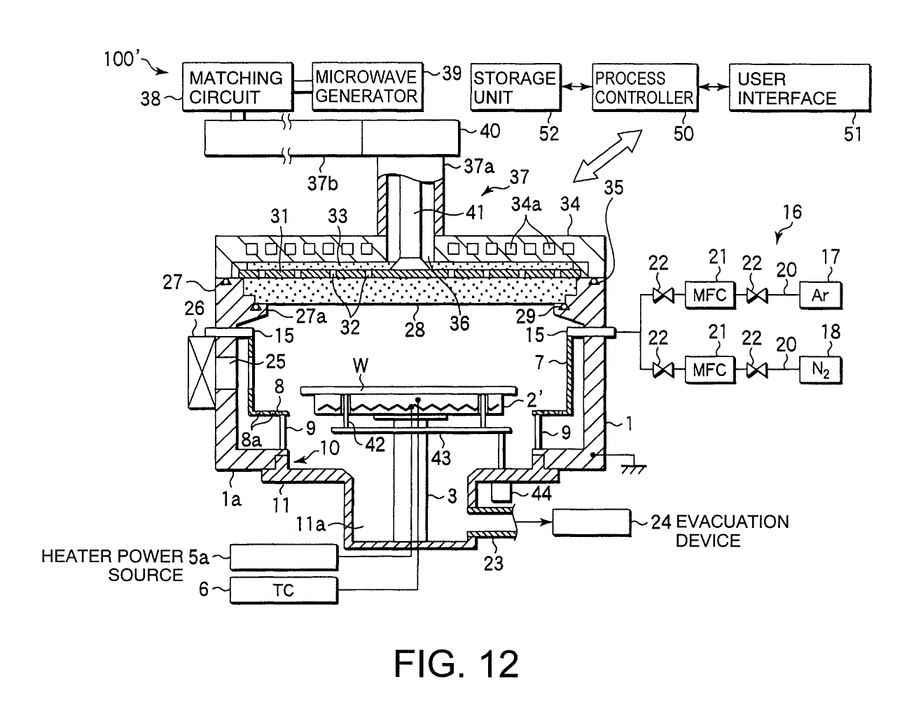

A second embodiment of the present invention will now be described. FIG. 12 is a cross-sectional diagram showing a plasma processing apparatus according to a second embodiment of the present invention. The plasma processing apparatus 100′ of FIG. 12 differs from the plasma processing apparatus 100 of FIG. 1 only in the structure of a susceptor, and hence the same components are given the same reference numerals and a description thereof will be omitted.

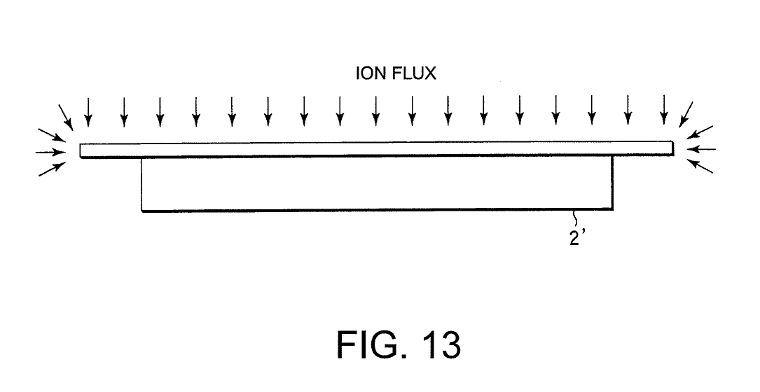

The plasma processing apparatus 100′ includes a susceptor 2′ having a smaller diameter than the diameter of a wafer W. As shown in the enlarged view of the susceptor 2′of FIG. 13, when the wafer W is placed on the susceptor 2′, a peripheral portion of the wafer W projects from the edge of the susceptor 2′, so that a plasma generating space is allowed to be in contact with a peripheral region of the back surface of the wafer W and the plasma can reach a peripheral portion of the wafer W without being blocked by the susceptor. Accordingly, the amount of ion flux increases in the peripheral portion and the amount of active species, contributing to nitridation, increases in a peripheral region of the front surface of the wafer W. This can eliminate the tendency to low amount of nitrogen introduced into the peripheral region of the front surface of the wafer W, making it possible to perform nitridation processing with high in-plane uniformity.

The region of the wafer W, for which the increase in the amount of nitrogen introduced is intended, can be adjusted by adjusting the radial length of the projecting peripheral portion of the wafer W depending on the size of the wafer W and the nitridation conditions.

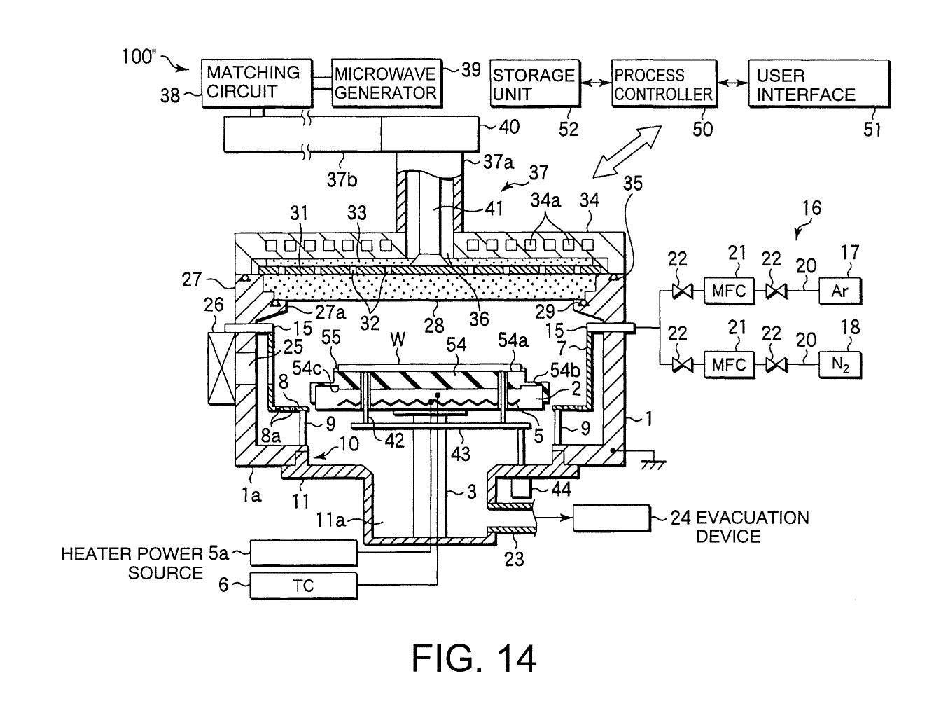

A third embodiment of the present invention will now be described. FIG. 14 is a cross-sectional diagram showing a plasma processing apparatus according to a third embodiment of the present invention. The plasma processing apparatus 100″ of FIG. 14 differs from the plasma processing apparatus 100 of FIG. 1 only in the structure around the susceptor, and hence the same components are given the same reference numerals and a description thereof will be omitted.

The plasma processing apparatus 100″ of this embodiment is provided with a quartz susceptor cover 54 which covers the entire upper surface of the susceptor 2. The susceptor 2 and the susceptor cover 54 constitute a wafer stage section.

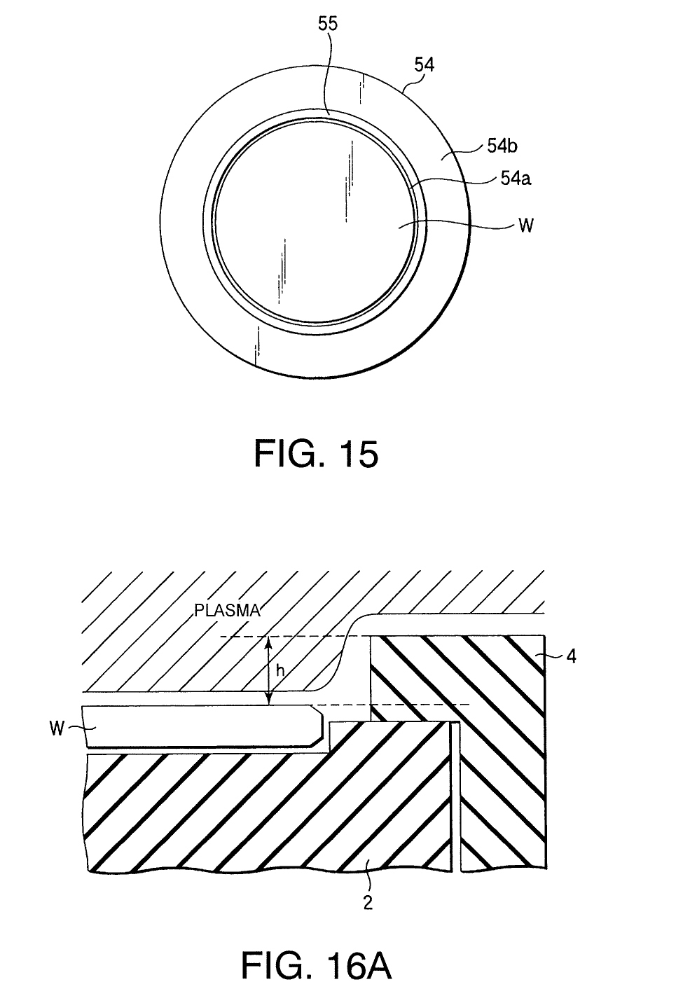

As shown also in the plan view of FIG. 15, the susceptor cover 54 has a receiving surface 54a for placing a wafer W on it. The receiving surface 54a is provided with a guide ring 55 for guiding the wafer W and preventing displacement of the wafer W. The guide ring 55 has a height which is smaller than the thickness of the wafer W. The susceptor cover 54 also has a lower-level surface 54b positioned around and below the receiving surface 54a. A generally vertical stage wall 54b is formed between the receiving surface 54a and the lower-level surface 54b. The stage wall 54b may be inclined.

As with the first embodiment, a recess (counterbore) is formed centrally in the susceptor 2, while a protruding portion 54c, corresponding to the recess of the susceptor 2, is formed centrally in the lower surface of the susceptor cover 54, whereby the susceptor cover 54 is positioned. Instead of the guide ring 55, it is possible to provide at least three guide pins equally spaced apart from each other. Further, instead of the provision of the counterbore in the susceptor 2, it is possible to provide a plurality of recessed portions in the upper surface of the susceptor 2 and provide a plurality of protruding portions, corresponding to the recessed portions, in the lower surface of the susceptor cover 54 and to engage the recessed and protruding portions. This can increase heating efficiency.

According to such plasma processing apparatus 100″, by carrying out plasma processing of a wafer W placed on the receiving surface 54a without raising the support pins 42, active species in a plasma can reach a peripheral region of the front surface of the wafer W at the same level as in a central region of the wafer W. This can eliminate the tendency to low nitridation rate in the peripheral region of the front surface of the wafer W.

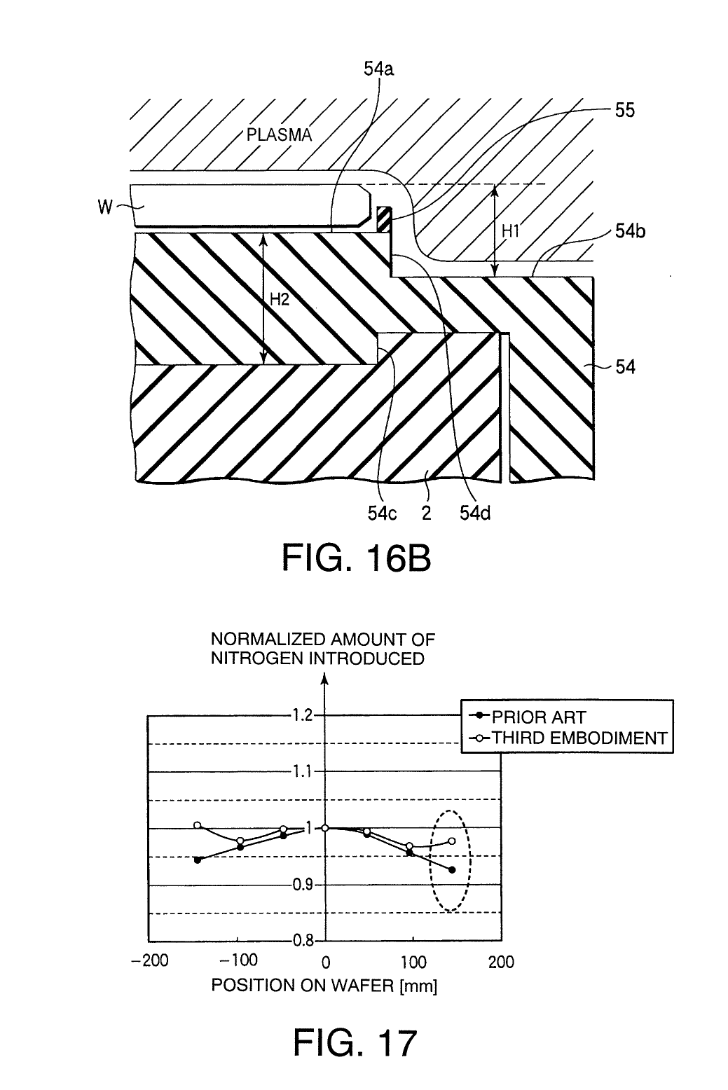

FIG. 16A shows an enlarged view of a portion of FIG. 5, illustrating a wafer W placed on the susceptor 2 in a conventional apparatus in which the ring-shaped susceptor cover 4 is present on the susceptor 2 as in FIG. 1. Because of the presence of the ring-shaped susceptor cover 4, whose top is positioned a distance “h” above the wafer W, around the wafer W, the lower end of a plasma, existing in an area around the periphery of the wafer W, is higher by the distance “h” than that of the plasma existing over the wafer W. Thus, due to the presence of the susceptor cover 4, the plasma exists at a distance from the edge of the wafer W in the area around the periphery of the wafer W. This leads to lower amount of active species supplied to a peripheral region of the front surface of the wafer W compared to the amount of active species supplied to a central region of the front surface.

It will be appreciated from the above that the presence of nothing around the periphery of the wafer W is effective for the elimination of the tendency to low amount of nitrogen introduced into a peripheral region of the front surface of the wafer W. Elimination of the susceptor cover 4 is effective for that purpose.

However, because the thickness of the wafer W is less than 1 mm, it is difficult to make a sufficient amount of plasma present in the vicinity of the periphery of the wafer W merely by eliminating the susceptor cover 4. In addition, the susceptor 2, made of an Al-containing ceramic such as AlN, will be etched by the plasma, which may cause contamination of the wafer.

In this embodiment, the susceptor cover 54 as shown in FIG. 16B is provided on the susceptor 2 so that no member that blocks a plasma exists around the periphery of the wafer W. Further, the lower-level surface 54b, whose level is lower than the receiving surface 54a and lower than the front surface of the wafer W by a distance H1, is provided around the periphery of the wafer W so that the lower end of a plasma, existing around the periphery of the wafer W, will be positioned the distance H1 below the front surface of the wafer W. This allows a plasma, existing around the periphery of the wafer W, to be positioned nearer to the periphery of the wafer W, and ideally positioned at the same distance to the periphery of the wafer W as the distance of a plasma, existing over a central region of the wafer W, to the wafer W. This can increase the amount of active species in plasma, supplied to a peripheral region of the front surface of the wafer W, and can make the amount nearer to the amount of active species supplied to a central region of the front surface of the wafer W. It thus becomes possible to increase the amount of nitrogen introduced into the peripheral region of the front surface of the wafer W and enhance the in-plane uniformity of the amount of nitrogen introduced. In addition, in this embodiment etching of the susceptor 2 by plasma can be avoided, and therefore, there is no increased contamination of the wafer W. The distance H1 (height of the front surface of the wafer

W from the lower-level surface 54b) is preferably 2 to 12 mm. This can further enhance the in-plane uniformity of the amount of nitrogen introduced. In view of uniform heating of the wafer W, etc., the distance H1 is more preferably 2.5 to 6.5 mm. If the thickness H2 of the susceptor cover 54 (see FIG. 16B) is too small, a sufficient distance H1 cannot be ensured. If the thickness H2 is too large, on the other hand, the efficiency of heating of the wafer W and the uniformity of the heating will be low because of the large distance between the heater and the wafer W, leading to low uniformity of the amount of nitrogen introduced. From such viewpoints, the thickness H2 is preferably 2 to 6.5 mm. Further, the distance H1 is preferably not more than the thickness H2, i.e. H1≦H2. In the case of H1>H2, the production of the susceptor cover 54 is difficult.

Unlike the first and second embodiments, in this embodiment a plasma generating space is not brought into contact with a peripheral region of the back surface of the wafer W. Nevertheless, the amount of active species in a plasma, supplied to a peripheral region of the front surface of the wafer W, can be increased and therefore the amount of nitrogen introduced into the peripheral region can be increased also according to this embodiment by allowing no member that blocks the plasma to exist around the periphery of the wafer W and by lowering the plasma in an area around the periphery of the wafer W.

When a wafer W is supported on pins in a raised position as in the first embodiment, a plasma will enter the gap between the susceptor 2 and the wafer W. There is, therefore, a fear of contamination of the wafer W. In contrast, this embodiment is free from such contamination.

An experiment was conducted in which nitridation processing of a wafer was carried out by using the apparatus of FIG. 1 without “pin up” (according to prior art), and nitridation processing of a wafer was also carried out by using the apparatus of FIG. 14 of this embodiment with the distance H1 (=thickness H2) of 6.5 mm, and the uniformity of the amount of nitrogen introduced was determined. The processing conditions were as follows: pressure in the chamber 45 Pa (337 mTorr); Ar gas flow rate 2000 mL/min (sccm), N₂ gas flow rate 100 mL/min (sccm); microwave power 1500 W; and processing time 60 sec. The results are shown in FIG. 17. FIG. 17 is a graph showing the uniformity of the amount of nitrogen introduced, in which the abscissa represents radial position on the wafer and the ordinate represents the amount of nitrogen introduced, normalized with the amount at the center of the wafer as 1. The data in the Figure verifies that compared to the prior art, the amount of nitrogen introduced into a peripheral region of the front surface of the wafer can be increased and the in-plane uniformity of the amount of nitrogen introduced can be enhanced according to this embodiment. The quotient 1σ/average (σ: standard deviation), which is an index of variation in the amount of nitrogen introduced, was 2.18 for the prior art and 1.17 for this embodiment.

Next, an experiment was conducted in which nitridation processing of a wafer was carried out by using the apparatus of FIG. 1 without “pin up”, and nitridation processing of a wafer was also carried out by using the apparatus of FIG. 14 of this embodiment with varying distances H1 (=thickness H2) of 2.5 mm, 4.5 mm and 6.5 mm. The processing conditions were as follows: Conditions A: pressure in the chamber 45 Pa (337 mTorr); Ar gas flow rate 2000 mL/min (sccm), N₂ gas flow rate 40 mL/min (sccm); microwave power 1100 W; and processing time 60 sec. Conditions B: pressure in the chamber 45 Pa (337 mTorr); Ar gas flow rate 2000 mL/min (sccm), N₂ gas flow rate 100 mL/min (sccm); microwave power 1500 W; and processing time 60 sec.

After the nitridation processing, the amount of nitrogen introduced was measured at various radial positions on each wafer and the uniformity was determined in terms of “range/2×average” and “1σ/average”.

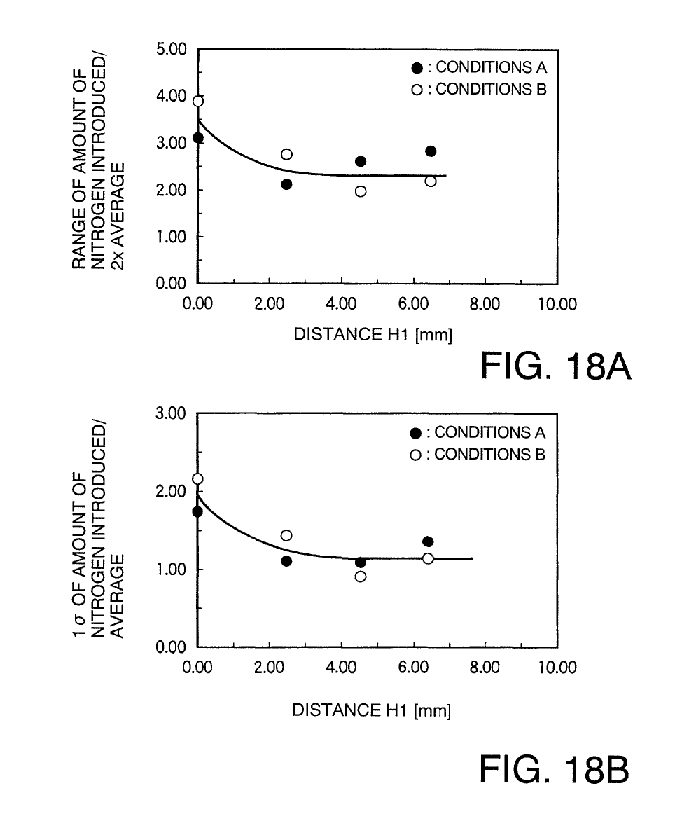

The results are shown in FIGS. 18A and 18B. FIG. 18A is a diagram showing the relationship between distance H1 and “range/2×average”, and FIG. 18B is a diagram showing the relationship between distance H1 and “1σ/average”. In these Figures, the black dots represent the conditions A and the white dots represent the conditions B, and the data at distance H1=0 represent the data for the nitridation processing carried out by means of the prior art apparatus. The data in the Figures demonstrates that, as compared to the prior art, variation in the amount of nitrogen introduced is significantly small with the varying distances H1 in the range of 2.5 to 6.5 mm according to this embodiment. The data thus verifies that this embodiment enables uniform nitridation processing.

It will be understood by those skilled in the art that the present invention is not limited to the particular embodiments described above, but it is intended to cover modifications within the inventive concept.

For example, while the present invention has been described with reference to microwave plasma nitridation processing, the present invention can also be applied to plasma processing using other types of plasma, especially a self-generating plasma like a microwave plasma, such as an inductive coupled plasma, a surface wave plasma, a surface-reflected wave plasma or a magnetron plasma.

While the present invention has been described with reference to plasma nitridation processing, the present invention can also be applied to other types of plasma processing, such as oxidation processing, CVD film-forming processing, plasma etching processing, etc.

Further, while the present invention has been described with reference to processing of a semiconductor wafer as a processing object, the present invention can of course be applied to other types of processing objects, for example, a glass substrate for an FPD.

1-22. (canceled)

23. A plasma processing method comprising:
placing a processing object on a stage disposed in a processing container;
forming a plasma in the processing container; and
carrying out plasma processing of the front surface of the processing object using the plasma,
wherein the stage has a step that defines a central upper surface for placing the process object thereon and a peripheral upper surface surrounding the central upper surface immediately outside the central upper surface, the central upper surface has a first level and the peripheral upper surface has a second level lower than the first level, and the central upper surface has a profile approximately the same as that of the process object, whereby the plasma formed in the processing container is lowered to a level lower than the process object placed on the central upper surface so that a periphery of the process object is surrounded by the plasma.

24. The plasma processing method according to claim 23, wherein the stage includes a susceptor of a ceramic and a susceptor cover of quartz covering an upper portion of the susceptor, and the central upper surface and the peripheral upper surface are provided by the susceptor cover.

25. The plasma processing method according to claim 23, wherein a guide member is provided on the central upper surface to guide a periphery of the process object, and the guide member has a height smaller than a thickness of the process object.

26. The plasma processing method according to claim 23, wherein a height difference between the first level and the second level is determined such that a distance between the peripheral upper surface and the front surface of the process object placed on the central upper surface is within a range of 2 mm to 12 mm.

27. The plasma processing method according to claim 23, wherein the plasma is formed by applying microwave to a processing gas supplied into the processing container.

28. A plasma processing apparatus comprising:
a processing container for housing a processing object;
a stage, disposed in the processing container, for placing the processing object thereon;
a gas supply mechanism that supplies a processing gas into the processing container; and
a plasma-forming device that forms a plasma of the processing gas in the processing container,
wherein the stage has a step that defines a central upper surface for placing the process object thereon and a peripheral upper surface surrounding the central upper surface immediately outside the central upper surface, the central upper surface has a first level and the peripheral upper surface has a second level lower than the first level, and the central upper surface has a profile approximately the same as that of the process object, whereby the plasma generated in the processing container can be lowered to a level lower than the process object placed on the central upper surface to allow a periphery of the process object to be surrounded by the plasma.

29. The plasma processing apparatus according to claim 28, wherein the stage includes a susceptor of a ceramic and a susceptor cover of quartz covering an upper portion of the susceptor, and the central upper surface and the peripheral upper surface are provided by the susceptor cover.

30. The plasma processing method according to claim 28, wherein a guide member is provided on the central upper surface to guide a periphery of the process object, and the guide member has a height smaller than a thickness of the process object.

31. The plasma processing method according to claim 28, wherein a height difference between the first level and the second level is determined such that a distance between the peripheral upper surface and the front surface of the process object placed on the central upper surface is within a range of 2 mm to 12 mm.

32. The plasma processing method according to claim 28, wherein the plasma forming device includes a microwave generator for generating a microwave and a plane antenna having a plurality of slots for introducing the microwave into the processing container.
